(19) United States
(12) Patent Application Publication
(10) Pub. No.: US 2020/0361816 A1
(43) Pub. Date: Nov. 19, 2020

(54) GLASS, CASING, AND ELECTRONIC DEVICE

(71) Applicant: SONY SEMICONDUCTOR SOLUTIONS CORPORATION, KANAGAWA (JP)

(72) Inventor: Takaaki HIRANO, KANAGAWA (JP)

(21) Appl. No.: 16/765,022

(22) PCT Filed: Sep. 18, 2018
(86) PCT No.: PCT/JP2018/034433

§ 371 Date: May 18, 2020

(30) Foreign Application Priority Data
Nov. 27, 2017 (JP) 2017-226956

(51) Int. Cl. C03C 19/00; H05K 5/03; C03C 21/00

(52) U.S. Cl. CPC C03C 19/00; H05K 5/0017; C03C 21/002; H05K 5/03

(57) ABSTRACT

To provide a glass with improved strength. Provided is a glass having at least a first face and a second face facing each other, and a third face connecting the first face to the second face. Each of the first face, the second face, and the third face contains metal atoms. The average concentration of the metal atoms in a first side region formed by the first face and the third face is lower than the average concentration of the metal atoms in each of the first face and the third face.

### TECHNICAL FIELD

The present technology relates to a glass, a casing, and an electronic device.

### BACKGROUND ART

A glass is used for a device such as a smart phone, a digital camera, a personal data assistance (PDA), or a touch panel display, which tends to be more and more popular in the market.

For example, a technique relating to a reinforced glass and a method for manufacturing the reinforced glass has been proposed (see Patent Documents 1 to 3).

### CITATION LIST

### Patent Document

Patent Document 1: Japanese Patent Application Laid-Open No. 2015-174777
Patent Document 2: Japanese Patent Application Laid-Open No. 2016-121067
Patent Document 3: Japanese Patent Application Laid-Open No. 2016-074564

### SUMMARY OF THE INVENTION

### Problems to be Solved by the Invention

However, according to the techniques proposed in Patent Documents 1 to 3, it may be impossible to further improve the strength of a glass.

Therefore, the present technology has been achieved in view of such a situation, and a main object of the present technology is to provide a glass with improved strength, and a casing and an electronic device including the glass.

### Solutions to Problems

The present inventor made intensive studies in order to solve the above-described object, and as a result, has succeeded in dramatically improving the strength of a glass, and has completed the present technology.

That is, the present technology provides a glass having at least a first face and a second face facing each other, and a third face connecting the first face to the second face, in which each of the first face, the second face, and the third face contains metal atoms, and the average concentration of the metal atoms in a first side region formed by the first face and the third face is lower than the average concentration of the metal atoms in each of the first face and the third face.

In the glass according to the present technology, the first side region may have a chamfered shape, and the chamfered shape of the first side region may be a C-chamfered shape or an R-chamfered shape.

In the glass according to the present technology, the average concentration of the metal atoms in a second side region formed by the second face and the third face may be lower than the average concentration of the metal atoms in each of the second face and the third face.

In the glass according to the present technology, the second side region may have a chamfered shape, and the chamfered shape of the second side region may be a C-chamfered shape or an R-chamfered shape.

The glass according to the present technology may further have at least a fourth face connecting the first face to the second face. In the glass according to the present technology, the fourth face contains the metal atoms, and the average concentration of the metal atoms in a vertex portion formed by the first side region and a third side region formed by the first face and the fourth face may be lower than the average concentration of the metal atoms in each of the first side region and the third side region.

The glass according to the present technology may further have at least a fourth face connecting the first face to the second face. In the glass according to the present technology, the fourth face contains the metal atoms, and the average concentration of the metal atoms in a vertex portion formed by a second side region formed by the second face and the third face and a fourth side region formed by the second face and the fourth face may be lower than the average concentration of the metal atoms in each of the second side region and the fourth side region.

In the glass according to the present technology, at least one of the first face and the second face may be a flat face.

In the glass according to the present technology, at least one of the first face and the second face may be a curved face.

Furthermore, the present technology provides a casing including the glass according to the present technology.

Moreover, the present technology provides an electronic device including the glass according to the present technology.

### Effects of the Invention

The present technology can further improve the strength of a glass. Note that the effects described here are not necessarily limited, and may be any of the effects described in the present disclosure.

### BRIEF DESCRIPTION OF DRAWINGS

FIG. 1 is a perspective view illustrating a configuration example of a glass according to a first embodiment to which the present technology is applied.

FIG. 2 is a perspective view illustrating a configuration example of a glass according to a second embodiment to which the present technology is applied.

FIG. 3 is a perspective view illustrating a configuration example of an electronic device according to a sixth embodiment to which the present technology is applied.

FIG. 4 is a perspective view illustrating a configuration example of a glass according to a third embodiment to which the present technology is applied.

FIG. 5 is a cross-sectional view illustrating a configuration example of the glass according to the third embodiment to which the present technology is applied.

FIG. 6 is a cross-sectional view illustrating a configuration example of the glass according to the third embodiment to which the present technology is applied.

FIG. 7 is a perspective view illustrating a configuration example of a glass according to a fourth embodiment to which the present technology is applied.

FIG. 8 is a diagram for explaining a relationship between an ion concentration and a distance from a glass surface.

FIG. 9 is a diagram for explaining a relationship between an ion concentration and a distance from a glass surface.

FIG. 10 is a diagram for explaining a relationship between an ion concentration and a distance from a glass surface.

FIG. 11 is a diagram for explaining a relationship between an ion concentration and a distance from a glass surface.

FIG. 12 is a diagram for explaining a method for manufacturing a glass according to the present technology.

FIG. 13 is a diagram for explaining a method for manufacturing the glass according to the present technology.

FIG. 14 is a diagram for explaining a configuration of the glass according to the first embodiment to which the present technology is applied.

FIG. 15 is a diagram for explaining a relationship between an internal stress (MPa) and the width (μm) of a reinforcement reduction region.

FIG. 16 is a diagram illustrating a distribution of a stress with respect to the width (μm) of a reinforcement reduction region.

FIG. 17 is a diagram illustrating an example of use of the electronic device according to the sixth embodiment to which the present technology is applied.

FIG. 18 is a functional block diagram of an example of the electronic device according to the sixth embodiment to which the present technology is applied.

### MODE FOR CARRYING OUT THE INVENTION

Hereinafter, a preferred embodiment for carrying out the present technology will be described. The embodiments described below exemplify representative embodiments of the present technology, and the scope of the present technology is not narrowly interpreted by the embodiments.

Note that the description will be made in the following order.

1. Summary of the present technology

2. First Embodiment (Example 1 of glass)

3. Second embodiment (Example 2 of glass)

4. Third embodiment (Example 3 of glass)

5. Fourth embodiment (Example 4 of glass)

6. Fifth embodiment (example of casing)

7. Sixth Embodiment (example of electronic device)

8. Examples of use of electronic device to which the present technology is applied

### 1. Summary of the Present Technology

First, summary of the present technology will be described.

A surface glass may be broken when a mobile device falls under a use environment. A common solution therefor is a reinforcing method with a compressed glass. The compressed glass is a glass in which a compressive stress state is formed on a surface and a margin for cracks generated by a tensile stress is widened. A typical method for manufacturing the compressed glass includes a chemical reinforcing method for putting a glass in a tank and injecting large-sized atoms from a surface by ion exchange, and a method for rapidly cooling a glass at the time of glass molding to leave a residual compressive stress on an outer surface. These reinforcing methods have been successful, but there is still a need for a reinforcing method that generates a better result. As a disadvantage of such a conventional technique, an internal stress increases due to a stress of a reinforcing layer at an edge portion of a glass, the glass is crushed, and fragments of the glass become finer, which may increase danger or reduce strength disadvantageously. Therefore, for example, there is a technique for removing the disadvantage by attaching R to an end portion, enhancing the reinforcement of the entire end face, or conversely weakening the reinforcement of entire end face.

However, in the technique for simply enhancing the reinforcement of the entire end face, the internal stress of a side portion or a corner portion of a glass may increase, the glass may be crushed, and fragments of the glass may become finer. Conversely, in the technique for weakening the reinforcement of the entire end face, the stress of a face portion of a glass to be reinforced may be reduced, and the reinforcement may be weakened.

The present technology provides a glass maintaining a face reinforcing stress while reducing fracture of a side portion (side region) or a corner portion (vertex portion) of a glass (which may be chemically reinforced glass). An ion exchange amount in a side region (which may be a side) formed by faces of the glass or in a vertex portion formed by the side regions (which may be a vertex portion formed by sides) is reduced as compared with an ion exchange amount on a surface of a face, and an internal stress of a corner portion generated by ion exchange is reduced while the strength of the face is maintained, and crushing is reduced.

### 2. First Embodiment (Example 1 of Glass)

A glass according to a first embodiment of the present technology is a glass having at least a first face and a second face facing each other, and a third face connecting the first face to the second face, in which each of the first face, the second face, and the third face contains metal atoms, and the average concentration of the metal atoms in a first side region formed by the first face and the third face is lower than the average concentration of the metal atoms in each of the first face and the third face.

In the glass according to the first embodiment of the present technology, the average concentration of the metal atoms in a second side region formed by the second face and the third face may be lower than the average concentration of the metal atoms in each of the second face and the third face.

The glass according to the first embodiment of the present technology may have a fourth face connecting the first face to the second face, and the fourth face may contain metal atoms. The average concentration of the metal atoms in a third side region formed by the first face and the fourth face may be lower than the average concentration of the metal atoms in each of the first face and the fourth face. The average concentration of the metal atoms in a fourth side region formed by the second face and the fourth face may be lower than the average concentration of the metal atoms in each of the second face and the fourth face.

The glass according to the first embodiment of the present technology may have a fifth face connecting the first face to the second face, and the fifth face may contain metal atoms. The average concentration of the metal atoms in a fifth side region formed by the first face and the fifth face may be lower than the average concentration of the metal atoms in each of the first face and the fifth face. The average concentration of the metal atoms in a sixth side region 56-1 formed by the second face and the fifth face may be lower than the average concentration of the metal atoms in each of the second face and the fifth face.

The glass according to the first embodiment of the present technology may have a sixth face connecting the first face to the second face, and the sixth face may contain metal atoms. The average concentration of the metal atoms in a seventh side region formed by the first face and the sixth face may be lower than the average concentration of the metal atoms in each of the first face and the sixth face. The average concentration of the metal atoms in an eighth side region 58-1 formed by the second face and the sixth face 6-1 may be lower than the average concentration of the metal atoms in each of the second face and the sixth face.

In the glass according to the first embodiment of the present technology, the average concentration of the metal atoms in a ninth side region formed by the third face and the fourth face may be lower than the average concentration of the metal atoms in each of the third face and the fourth face. The average concentration of the metal atoms in a tenth side region formed by the fourth face and the fifth face may be lower than the average concentration of the metal atoms in each of the fourth face and the fifth face. The average concentration of the metal atoms in an eleventh side region formed by the fifth face and the sixth face may be lower than the average concentration of the metal atoms in each of the fifth face and the sixth face. Moreover, the average concentration of the metal atoms in a twelfth side region formed by the sixth face and the third face may be lower than the average concentration of the metal atoms in each of the sixth face and the third face.

The first side region to the twelfth side region are preferably within a range influenced by an internal stress (tensile stress), but is not limited thereto. The range influenced by an internal stress (tensile stress) is, for example, a range of several μm to 100 μm from a glass surface in a case where the glass has a thickness of about 700 μm.

A concept of the metal atoms includes a state where the metal atoms are ionized, that is, metal ions. The metal atoms can be contained in the glass according to the first embodiment of the present technology by an ion exchange method. The ion exchange method refers to, for example, replacing an ion having a small ion radius (atomic radius) contained in a glass before ion exchange with an ion having a large ion radius (atomic radius). For example, the ion exchange method refers to replacing a Li ion contained in a glass before ion exchange with a Na ion, or replacing a Na ion contained in a glass before ion exchange with a K ion.

The shape of the glass according to the first embodiment of the present technology may be any shape. For example, the shape of the glass according to the first embodiment of the present technology may be a hexahedron or a polyhedron.

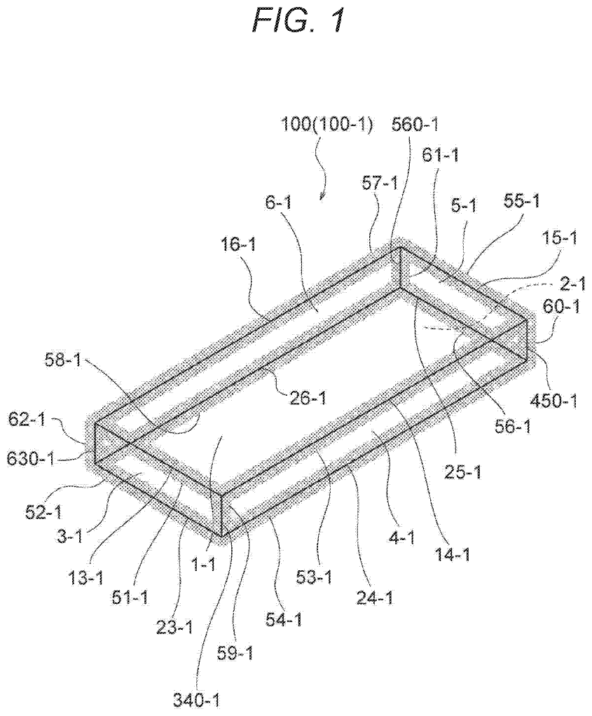

FIG. 1 illustrates a glass 100 (100-1 in FIG. 1) which is an example of the glass according to the first embodiment of the present technology. FIG. 1 is a perspective view of the hexahedral glass 100-1.

The glass 100-1 has at least a first face 1-1 and a second face 2-1 facing each other, and a third face 3-1 connecting the first face 1-1 to the second face 2-1. Each of the first face 1-1, the second face 2-1, and the third face 3-1 contains metal atoms. The average concentration of the metal atoms in a first side region 51-1 formed by the first face 1-1 and the third face 3-1 is lower than the average concentration of the metal atoms in each of the first face 1-1 and the third face 3-1. The first side region 51-1 is a region including a first side 13-1.

In the glass 100-1, the average concentration of the metal atoms in a second side region 52-1 formed by the second face 2-1 and the third face 3-1 is lower than the average concentration of the metal atoms in each of the second face 2-1 and the third face 3-1. The second side region 52-1 is a region including a second side 23-1.

The glass 100-1 has a fourth face 4-1 connecting the first face 1-1 to the second face 2-1. The fourth face 4-1 contains metal atoms. The average concentration of the metal atoms in a third side region 53-1 formed by the first face 1-1 and the fourth face 4-1 is lower than the average concentration of the metal atoms in each of the first face 1-1 and the fourth face 4-1. The average concentration of the metal atoms in a fourth side region 54-1 formed by the second face 2-1 and the fourth face 4-1 is lower than the average concentration of the metal atoms in each of the second face 2-1 and the fourth face 4-1. The third side region 53-1 is a region including a third side 14-1. The fourth side region 54-1 is a region including a fourth side 24-1.

The glass 100-1 has a fifth face 5-1 connecting the first face 1-1 to the second face 2-1. The fifth face 5-1 contains metal atoms. The average concentration of the metal atoms in a fifth side region 55-1 formed by the first face 1-1 and the fifth face 5-1 is lower than the average concentration of the metal atoms in each of the first face 1-1 and the fifth face 5-1. The average concentration of the metal atoms in a sixth side region 56-1 formed by the second face 2-1 and the fifth face 5-1 is lower than the average concentration of the metal atoms in each of the second face 2-1 and the fifth face 5-1. The fifth side region 55-1 is a region including a fifth side 15-1. The sixth side region 56-1 is a region including a sixth side 25-1.

The glass 100-1 has a sixth face 6-1 connecting the first face 1-1 to the second face 2-1. The sixth face 6-1 contains metal atoms. The average concentration of the metal atoms in a seventh side region 57-1 formed by the first face 1-1 and the sixth face 6-1 is lower than the average concentration of the metal atoms in each of the first face 1-1 and the sixth face 6-1. The average concentration of the metal atoms in an eighth side region 58-1 formed by the second face 2-1 and the sixth face 6-1 is lower than the average concentration of the metal atoms in each of the second face 2-1 and the sixth face 6-1. The seventh side region 57-1 is a region including a seventh side 16-1. The eighth side region 58-1 is a region including an eighth side 26-1.

In the glass 100-1, the average concentration of the metal atoms in a ninth side region 59-1 formed by the third face 3-1 and the fourth face 4-1 is lower than the average concentration of the metal atoms in each of the third face 3-1 and the fourth face 4-1. The average concentration of the metal atoms in a tenth side region 60-1 formed by the fourth face 4-1 and the fifth face 5-1 is lower than the average concentration of the metal atoms in each of the fourth face 4-1 and the fifth face 5-1. The average concentration of the metal atoms in an eleventh side region 61-1 formed by the fifth face 5-1 and the sixth face 6-1 is lower than the average concentration of the metal atoms in each of the fifth face 5-1 and the sixth face 6-1. Moreover, the average concentration of the metal atoms in a twelfth side region 62-1 formed by the sixth face 6-1 and the third face 3-1 is lower than the average concentration of the metal atoms in each of the sixth face 6-1 and the third face 3-1. The ninth side region 59-1 is a region including a ninth side 340-1. The tenth side region 60-1 is a region including a tenth side 450-1. The eleventh side region 61-1 is a region including an eleventh side 560-1. The twelfth side region 62-1 is a region including a twelfth side 630-1.

FIG. 14 is a diagram for explaining a configuration of the glass according to the first embodiment of the present technology. FIG. 14(a) is a perspective view of a glass 100-14a. FIG. 14(b) is an enlarged cross-sectional view of a hatched portion R-14a in Q-14a of the glass 100-14a.

Referring to FIG. 14(b), the glass 100-14b has a first face 1-14b, a second face 2-14b, a fifth face 5-14b connecting the first face 1-14b to the second face 2-14b, and an unreinforced region 520-14b. A reinforced region 510-14b-1 is formed on the first face 1-14b, a reinforced region 510-14b-2 is formed on the second face 2-14b, and a reinforced region 510-14b-3 is formed on the fifth face 5-14b. In addition, a reinforcement reduction region 500-14b-2 is formed by the first face 1-14b and the fifth face 5-14b, and a reinforcement reduction region 500-14b-1 is formed by the second face 2-14b and the fifth face 5-14b. The reinforcement reduction region 500-14b-2 corresponds to the fifth side region, and the reinforcement reduction region 500-14b-1 corresponds to the sixth side region. The reinforcement reduction region 500-14b-1 has a width 1 in a direction along the second face 2-14b, and has a width 2 in a direction along the fifth face 5-14b. The reinforcement reduction region 500-14b-2 has a width 3 in a direction along the fifth face 5-14b, and has a width 4 in a direction along the first face 1-14b. The lengths of the widths 1 to 4 may be the same or different.

In each of the reinforcement reduction regions 500-14b-1 and 500-14b-2, the amount of metal atoms (metal ions) having a large atomic radius to be ion-exchanged is smaller than the amount in each of the reinforced regions 510-14b-1 to 510-14b-3. By inclusion of the reinforcement reduction regions 500-14b-1 and 500-14b-2 in the glass 100-14b, an internal stress (tensile stress) in the fifth side region and the sixth side region (corner portion of the glass 100-14b ) can be reduced to prevent crushing and fracture while a reinforcing stress (compressive stress) P-14b-1 of the first face 1-14b, a reinforcing stress (compressive stress) P14-b-2 of the second face 2-14b, and a reinforcing stress (compressive stress) P14b-3 of the fifth face 5-14b are maintained.

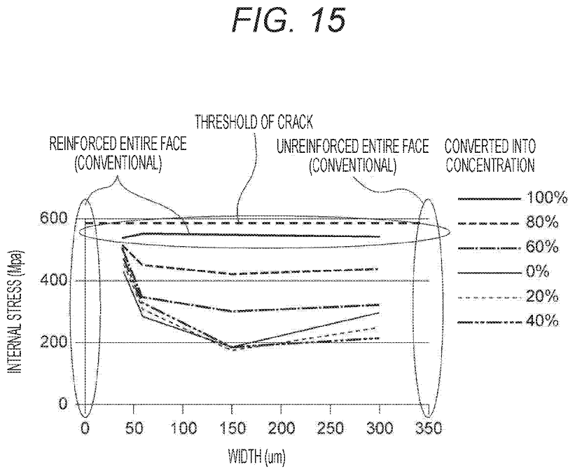

FIG. 15 is a diagram for explaining a relationship between an internal stress (tensile stress) (MPa) and the width (μm) of a reinforcement reduction region when a concentration ratio of the average concentration of the metal atoms in a reinforcement reduction region to the average concentration of the metal atoms in a reinforced region is changed from 0% to 100%. The width (μm) of the reinforcement reduction region corresponds to any one of the widths 1 to 4 illustrated in FIG. 14(b). For example, a concentration ratio of “0%” indicates that the average concentration of the metal atoms having a large atomic radius in a reinforcement reduction region is 0 mol % (no ion exchange) similarly to the average concentration of the metal atoms having a large atomic radius in an unreinforced region, and a concentration ratio of “20%” indicates that the average concentration of the metal atoms having a large atomic radius in a reinforcement reduction region is 2 mol % when the average concentration of the metal atoms (having a large atomic radius) in a reinforced region is 10 mol %. A concentration ratio of “100%” indicates that no reinforcement reduction region is formed but only a reinforced region is formed.

As illustrated in FIG. 15, the lower the internal stress, the better. However, it can be confirmed that the width has an optimum value at a concentration ratio of 0% to 80%.

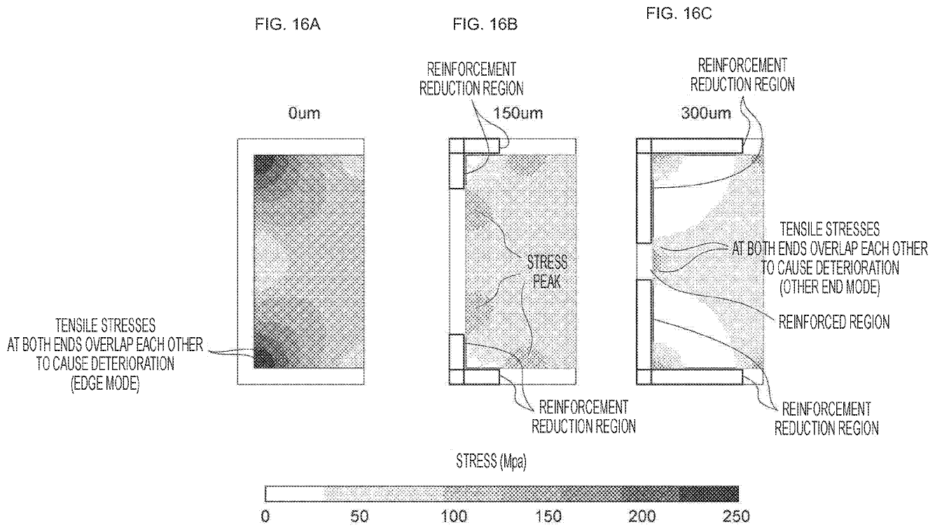

FIG. 16 is a diagram illustrating a distribution of an internal stress (tensile stress) with respect to the width (μm) of the reinforcement reduction region. FIG. 16(a) is a diagram illustrating a distribution of an internal stress (tensile stress) of a glass in which the width of the reinforcement reduction region is 0 μm (there is no reinforcement reduction region). FIG. 16(b) is a diagram illustrating a distribution of an internal stress (tensile stress) of a glass in which the width of the reinforcement reduction region is 150 μm. FIG. 16(c) is a diagram illustrating a distribution of an internal stress (tensile stress) of a glass in which the width of the reinforcement reduction region is 300 μm. The width of the reinforcement reduction region (μm) means a length (distance) from a surface of any one of the first face and the second face facing each other, and the third face (end face) connecting the first face to the second face in the glass, and corresponds to, for example, any one of the widths 1 to 4 illustrated in FIG. 14(b). A concentration ratio of the average concentration of the metal atoms in the reinforcement reduction region to the average concentration of the metal atoms in the reinforced region is 40%.

As illustrated in FIG. 16, in a case where there is no reinforcement reduction region (0 μm), stress influences on two faces overlap each other to generate a large internal stress. However, by inclusion of the reinforcement reduction region, a stress peak is dispersed, and the internal stress is reduced. When the reinforced layer reduction region is further expanded, stress peaks of the reinforced layer reduction region at other edges interfere with each other to generate a strong internal stress. This is a mechanism with an optimal value. Therefore, a case is effective where a width from an edge is equal to or longer than a stress influence distance and a distance from the reinforcement reduction region at another end is equal to or longer than the stress influence distance.

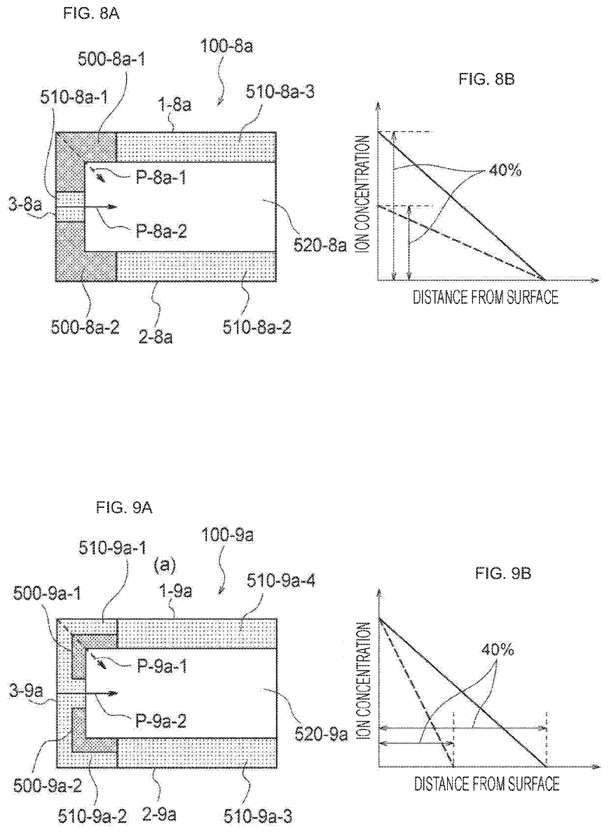

FIG. 8 is a diagram for explaining a relationship between a metal ion concentration and a distance from a glass surface. FIG. 8(a) is a cross-sectional view when a glass 100-8a is cut in a thickness direction. FIG. 8(b) is a graph illustrating a metal ion concentration with respect to a distance from a glass surface. The metal ion concentration in a direction of arrow P-8a-1 (broken line) illustrated in FIG. 8(a) corresponds to the broken line in the graph illustrated in FIG. 8(b). The metal ion concentration in a direction of arrow P-8a-2 (solid line) illustrated in FIG. 8(a) corresponds to the solid line in the graph illustrated in FIG. 8(b). As illustrated in FIG. 8(b), the concentration ratio is 40%.

Referring to FIG. 8(a), the glass 100-8a has a first face 1-8a, a second face 2-8a, third face 3-8a connecting the first face 1-8a to the second face 2-8a, and an unreinforced region 520-8a. A reinforced region 510-8a-3 is formed on the first face 1-8a, a reinforced region 510-8a-2 is formed on the second face 2-8a, and a reinforced region 510-8a-1 is formed on the third face 3-8a. In addition, a reinforcement reduction region 500-8a-1 is formed on the first face 1-8a and the third face 3-8a, and a reinforcement reduction region 500-8a-2 is formed on the second face 2-8a and the third face 3-8a. The reinforcement reduction region 500-8a-1 corresponds to the first side region, and the reinforcement reduction region 500-8a-2 corresponds to the second side region. As is clear from FIG. 8, by reducing the concentration of the metal atoms on an outermost surface in each of the first side region and the second side region (reinforcement reduction region) as compared with the concentration on a face (reinforced region), the concentration of the metal atoms may be reduced.

FIG. 9 is a diagram for explaining a relationship between a metal ion concentration and a distance from a glass surface. FIG. 9(a) is a cross-sectional view when a glass 100-9a is cut in a thickness direction. FIG. 9(b) is a graph illustrating a metal ion concentration with respect to a distance from a glass surface. The metal ion concentration in a direction of arrow P-9a-1 (broken line) illustrated in FIG. 9(a) corresponds to the broken line in the graph illustrated in FIG. 9(b). The metal ion concentration in a direction of arrow P-9a-2 (solid line) illustrated in FIG. 9(a) corresponds to the solid line in the graph illustrated in FIG. 9(b). As illustrated in FIG. 9(b), a distance ratio from a surface (depth ratio) is 40%.

Referring to FIG. 9(a), the glass 100-9a has a first face 1-9a, a second face 2-9a, third face 3-9a connecting the first face 1-9a to the second face 2-9a, and an unreinforced region 520-9a. A reinforced region 510-9a-4 is formed on the first face 1-9a, a reinforced region 510-9a-3 is formed on the second face 2-9a, and reinforced regions 510-9a-1 and 510-9a-2 are formed on the third face 3-9a. In addition, a reinforcement reduction region 500-9a-1 is formed on the first face 1-9a and the third face 3-9a inside the glass 100-9a, and a reinforcement reduction region 500-9a-2 is formed on the second face 2-9a and the third face 3-9a inside the glass 100-9a. The reinforcement reduction region 500-9a-1 corresponds to the first side region, and the reinforcement reduction region 500-9a-2 corresponds to the second side region. As is clear from FIG. 9, by reducing a penetration distance from a surface of the metal atoms in the first side region and the second side region (reinforcement reduction region) as compared with a penetration distance from a face (reinforced region), the concentration of the metal atoms may be reduced.

FIG. 10 is a diagram for explaining a relationship between a metal ion concentration and a distance from a glass surface. FIG. 10(a) is a cross-sectional view when a glass 100-10a is cut in a thickness direction. FIG. 10(b) is a graph illustrating a metal ion concentration with respect to a distance from a glass surface. The metal ion concentration in a direction of arrow P-10a-1 (broken line) illustrated in FIG. 10(a) corresponds to the broken line in the graph illustrated in FIG. 10(b). The metal ion concentration in a direction of arrow P-10a-2 (solid line) illustrated in FIG. 10(a) corresponds to the solid line in the graph illustrated in FIG. 10(b).

Referring to FIG. 10(a), the glass 100-10a has a first face 1-10a, a second face 2-10a, third face 3-10a connecting the first face 1-10a to the second face 2-10a, and an unreinforced region 520-10a. A reinforced region 510-10a-3 is formed on the first face 1-10a, a reinforced region 510-10a-2 is formed on the second face 2-10a, and a reinforced region 510-10a-1 is formed on the third face 3-10a. In addition, a reinforcement reduction region 500-10a-1 is formed on the first face 1-10a and the third face 3-10a, and a reinforcement reduction region 500-10a-2 is formed on the second face 2-10a and the third face 3-10a. The reinforcement reduction region 500-10a-1 corresponds to the first side region, and the reinforcement reduction region 500-10a-2 corresponds to the second side region.

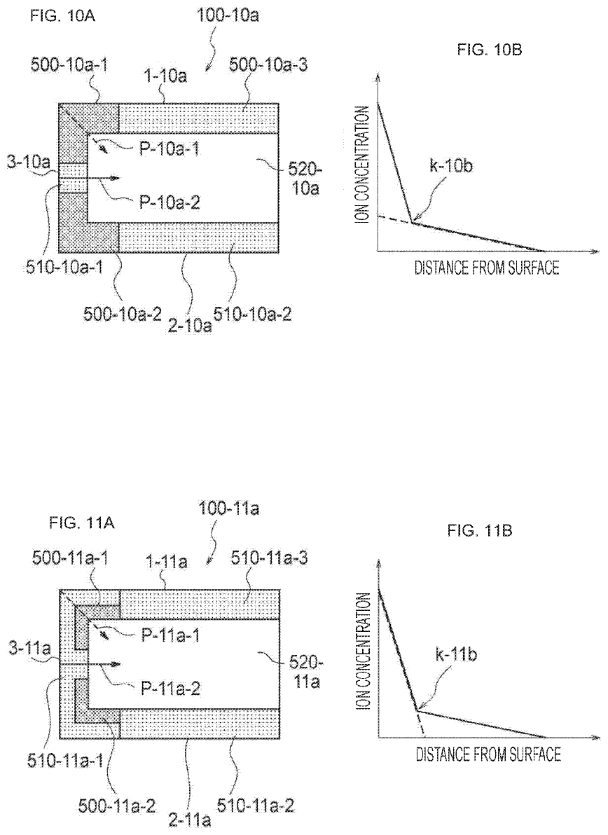

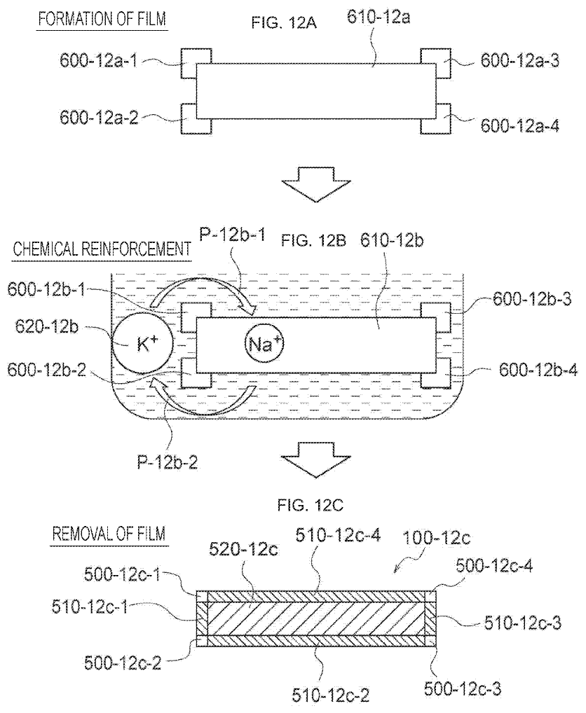

FIG. 11 is a diagram for explaining a relationship between a metal ion concentration and a distance from a glass surface. FIG. 11(a) is a cross-sectional view when a glass 100-11a is cut in a thickness direction. FIG. 11(b) is a graph illustrating a metal ion concentration with respect to a distance from a glass surface. The metal ion concentration in a direction of arrow P-11a-1 (broken line) illustrated in FIG. 11(a) corresponds to the broken line in the graph illustrated in FIG. 11(b). The metal ion concentration in a direction of arrow P-11a-2 (solid line) illustrated in FIG. 11(a) corresponds to the solid line in the graph illustrated in FIG. 11(b).

Referring to FIG. 11(a), the glass 100-11a includes a first face 1-11a, a second face 2-11a, third face 3-11a connecting the first face 1-11a to the second face 2-11a, and an unreinforced region 520-11a. A reinforced region 510-11a-3 is formed on the first face 1-11a, a reinforced region 510-11a-2 is formed on the second face 2-11a, and a reinforced region 510-11a-1 is formed on the third face 3-11a. In addition, a reinforcement reduction region 500-11a-1 is formed on the first face 1-11a and the third face 3-11a inside the glass 100-11a, and a reinforcement reduction region 500-11a-2 is formed on the second face 2-11a and the third face 3-11a inside the glass 100-11a. The reinforcement reduction region 500-11a-1 corresponds to the first side region, and the reinforcement reduction region 500-11a-2 corresponds to the second side region.

As is clear from FIGS. 10 and 11, by reducing a bent portion in a concentration distribution from an outermost surface of the metal atoms in the first side region and the second side region (reinforcement reduction region) (a bent portion k-10b illustrated in FIG. 10(b) and a bent portion k-11b illustrated in FIG. 11(b)) as compared with a bent portion in a concentration distribution from a face (reinforced region), the concentration of the metal atoms may be reduced. This is achieved by reducing the number of times of reinforcement in the first side region and the second side region (reinforcement reduction region) as compared with the number of times of reinforcement in a face (reinforced region). Times of reinforcement for deepening may be reduced, or times of reinforcement for shallowing may be reduced.

### [Method for Manufacturing the Glass According to the First Embodiment of the Present Technology]

Next, a method for manufacturing the glass according to the first embodiment of the present technology will be described. The glass according to the first embodiment of the present technology is obtained, for example, by the following example of a manufacturing method.

(Example 1 of Method for Manufacturing the Glass According to the First Embodiment of the Present Technology)

Example 1 of the method for manufacturing the glass according to the first embodiment of the present technology will be described with reference to FIG. 12. FIG. 12(a) is a diagram illustrating that films (masks) (600-12a-1 to 600-12a-4) are formed on a glass 610-12a. FIG. 12(b) is a diagram illustrating that films (masks) (600-12b-1 to 600-12b-4) are formed on a glass 610-12b, and the glass 610-12b is chemically reinforced in directions of arrows P-12b-1 and P-12b-2 (is subjected to ion exchange treatment from Na⁺ in the glass 610-12b (620-12b in FIG. 12(b)) to K⁺). FIG. 12(c) is a diagram illustrating that the films are removed to obtain a glass 100-12c.

The glass 100-12c has an unreinforced region 520-12c, reinforced regions 510-12c-1 to 510-12c-4, and reinforcement reduction regions 500-12c-1 to 51-12c-4. The reinforced regions 510-12c-1 to 510-12c-4 are formed on a face outside the unreinforced region 520-12c, and the reinforcement reduction regions 500-12c-1 to 51-12c-4 are formed in a side region outside the unreinforced region 520-12c.

As is clear from FIGS. 12(a) to 12(c), the glass according to the first embodiment of the present technology can be achieved by applying, as a mask, a material having a low ion penetration rate with respect to the glass, such as a resist, a tape, or a glass of a different composition to a side region or a vertex portion of the glass, and chemically reinforcing the glass by ion replacement to reduce the concentration of metal atoms at a side or a vertex of the glass. The type of ion replacement is not particularly limited as long as an ion is replaced with an ion having a larger metal atom size, for example, Na is replaced with K, or Li is replaced with Na.

(Example 2 of Method for Manufacturing the Glass According to the First Embodiment of the Present Technology)

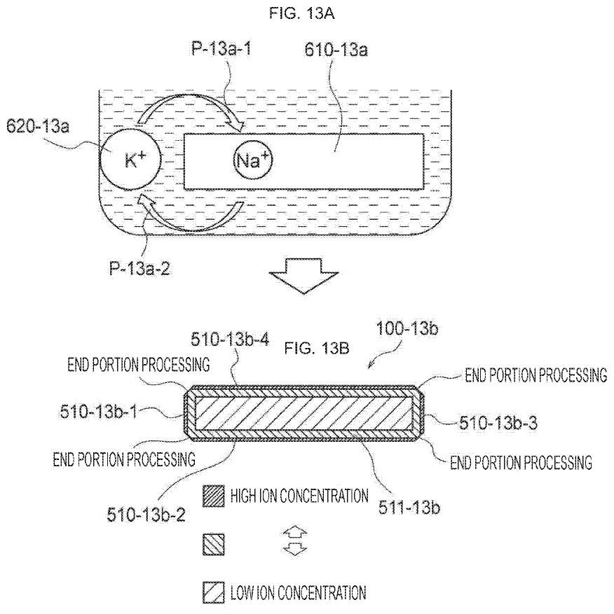

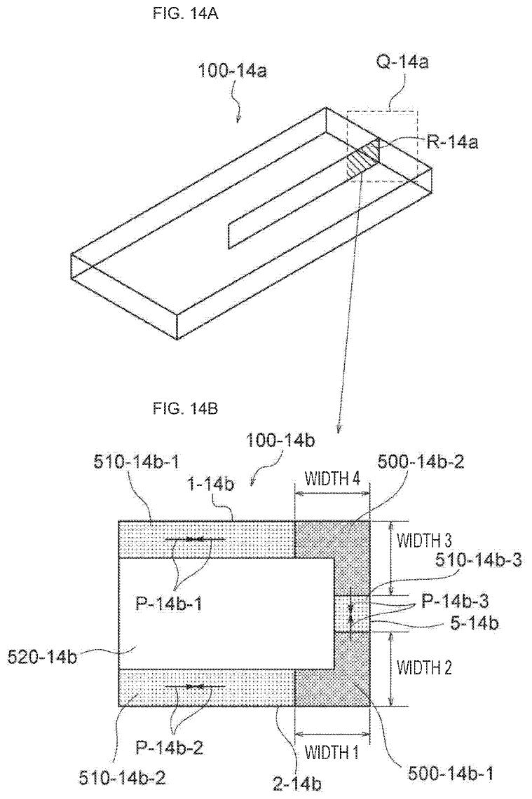

Example 2 of the method for manufacturing the glass according to the first embodiment of the present technology will be described with reference to FIG. 13.

FIG. 13(a) is a diagram illustrating that a glass 610-13a is chemically reinforced in directions of arrows P-13a-1 and P-13a-2 (is subjected to ion exchange treatment from Na⁺ in the glass 610-13a (620-13a in FIG. 13(a)) to K⁺). FIG. 13(b) is a diagram illustrating that an end portion of the glass is processed to obtain a glass 100-13b.

The glass 100-13c has a region having a low ion concentration, a region 511-13b having a high ion concentration, and regions 510-13b-1 to 510-13b-4 having a very high ion concentration. The region 511-13b having a high ion concentration is formed on a face outside a region having a low ion concentration. Moreover, the regions 510-13b-1 to 510-13b-4 having a very high ion concentration are formed on a face outside the region 511-13b having a high ion concentration. By processing an end portion, the region 511-13b having a high ion concentration is exposed in the end portion.

As is clear from FIGS. 13(a) and 13(b), the glass according to the first embodiment of the present technology can be achieved by polishing or etching a side or a vertex after reinforcing the glass to remove a reinforced region having the highest concentration on an outermost surface, and reducing the concentration of metal atoms at a side or a vertex of the glass.

### 3. Second Embodiment (Example 2 of Glass)

A glass according to a second embodiment of the present technology has the same configuration as the glass according to the first embodiment of the present technology described above. Moreover, in the glass according to the second embodiment of the present technology, at least one of a first face and a second face is a flat face. Alternatively, the glass according to the second embodiment of the present technology has the same configuration as the glass according to the first embodiment of the present technology described above. Moreover, in the glass according to the second embodiment of the present technology, at least one of a first face and a second face is a curved face.

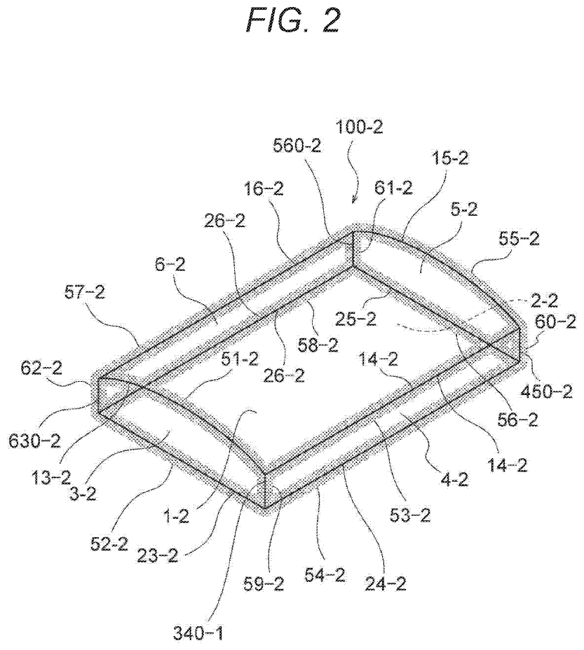

FIG. 2 illustrates a glass 100-2 which is an example of the glass according to the second embodiment of the present technology. FIG. 2 is a perspective view of the glass 100-2.

The glass 100-2 has at least a first face 1-2 and a second face 2-2 facing each other, and a third face 3-2 connecting the first face 1-2 to the second face 2-2. Each of the first face 1-2, the second face 2-2, and the third face 3-2 contains metal atoms. The average concentration of the metal atoms in a first side region 51-2 formed by the first face 1-2 and the third face 3-2 is lower than the average concentration of the metal atoms in each of the first face 1-2 and the third face 3-2. The first side region 51-2 is a region including a first side 13-2.

In the glass 100-2, the average concentration of the metal atoms in a second side region 52-2 formed by the second face 2-2 and the third face 3-2 is lower than the average concentration of the metal atoms in each of the second face 2-2 and the third face 3-2. The second side region 52-2 is a region including a second side 23-2.

The glass 100-2 has a fourth face 4-2 connecting the first face 1-2 to the second face 2-2. The fourth face 4-2 contains metal atoms. The average concentration of the metal atoms in a third side region 53-2 formed by the first face 1-2 and the fourth face 4-2 is lower than the average concentration of the metal atoms in each of the first face 1-2 and the fourth face 4-2. The average concentration of the metal atoms in a fourth side region 54-2 formed by the second face 2-2 and the fourth face 4-2 is lower than the average concentration of the metal atoms in each of the second face 2-2 and the fourth face 4-2. The third side region 53-2 is a region including a third side 14-2. The fourth side region 54-2 is a region including a fourth side 24-2.

The glass 100-2 has a fifth face 5-2 connecting the first face 1-2 to the second face 2-2. The fifth face 5-2 contains metal atoms. The average concentration of the metal atoms in a fifth side region 55-2 formed by the first face 1-2 and the fifth face 5-2 is lower than the average concentration of the metal atoms in each of the first face 1-2 and the fifth face 5-2. The average concentration of the metal atoms in a sixth side region 56-2 formed by the second face 2-2 and the fifth face 5-2 is lower than the average concentration of the metal atoms in each of the second face 2-2 and the fifth face 5-2. The fifth side region 55-2 is a region including a fifth side 15-2. The sixth side region 56-2 is a region including a sixth side 25-2.

The glass 100-2 has a sixth face 6-2 connecting the first face 1-2 to the second face 2-2. The sixth face 6-2 contains metal atoms. The average concentration of the metal atoms in a seventh side region 57-2 formed by the first face 1-2 and the sixth face 6-2 is lower than the average concentration of the metal atoms in each of the first face 1-2 and the sixth face 6-2. The average concentration of the metal atoms in an eighth side region 58-2 formed by the second face 2-2 and the sixth face 6-2 is lower than the average concentration of the metal atoms in each of the second face 2-2 and the sixth face 6-2. The seventh side region 57-2 is a region including a seventh side 16-2. The eighth side region 58-2 is a region including an eighth side 26-2.

In the glass 100-2, the average concentration of the metal atoms in a ninth side region 59-2 formed by the third face 3-2 and the fourth face 4-2 is lower than the average concentration of the metal atoms in each of the third face 3-2 and the fourth face 4-2. The average concentration of the metal atoms in a tenth side region 60-2 formed by the fourth face 4-2 and the fifth face 5-2 is lower than the average concentration of the metal atoms in each of the fourth face 4-2 and the fifth face 5-2. The average concentration of the metal atoms in an eleventh side region 61-2 formed by the fifth face 5-2 and the sixth face 6-2 is lower than the average concentration of the metal atoms in each of the fifth face 5-2 and the sixth face 6-2. Moreover, the average concentration of the metal atoms in a twelfth side region 62-2 formed by the sixth face 6-2 and the third face 3-2 is lower than the average concentration of the metal atoms in each of the sixth face 6-2 and the third face 3-2. The ninth side region 59-2 is a region including a ninth side 340-2. The tenth side region 60-2 is a region including a tenth side 450-2. The eleventh side region 61-2 is a region including an eleventh side 560-2. The twelfth side region 62-2 is a region including a twelfth side 630-2.

In the glass 100-2 in FIG. 2, the first face (an upper face in FIG. 2) 1-2 is a curved face, the second face 2-2 (a lower face in FIG. 2) is a flat face, and the third face (end face) 3-2, the fourth face (end face) 4-2, the fifth face (end face) 5-2, and the sixth face (end face) 602 which are side faces constituting an outer periphery of the glass 100-2 are flat faces. Note that at least one of the second face 2-2, the third face (end face) 3-2, the fourth face (end face) 4-2, the fifth face (end face) 5-2, and the sixth face (end face) 602 may be a curved face.

### 4. Third Embodiment (Example 3 of Glass)

A glass according to a third embodiment of the present technology has the same configuration as the glass according to the first embodiment of the present technology described above. Moreover, in the glass according to the third embodiment of the present technology, a first side region has at least a chamfered shape. The chamfered shape of the first side region may be a C-chamfered shape or an R-chamfered shape. In addition, in the glass according to the third embodiment of the present technology, a second side region may have a chamfered shape, and the chamfered shape of the second side region may be a C-chamfered shape or an R-chamfered shape.

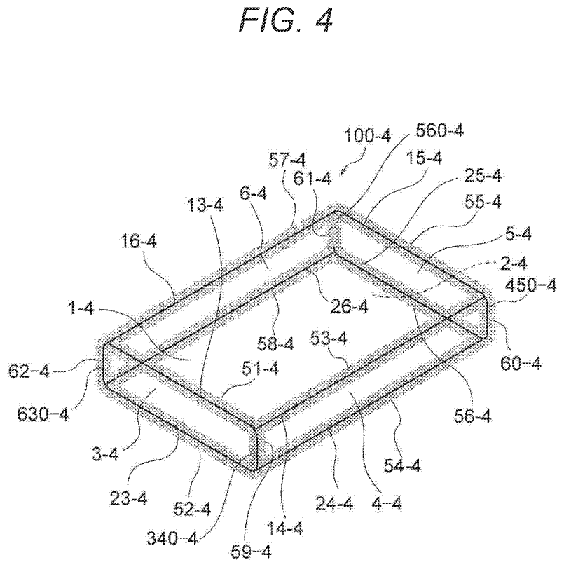

FIG. 4 illustrates a glass 100-4 which is an example of the glass according to the third embodiment of the present technology. FIG. 4 is a perspective view of the glass 100-4.

The glass 100-4 has at least a first face 1-4 and a second face 2-4 facing each other, and a third face 3-4 connecting the first face 1-4 to the second face 2-4. Each of the first face 1-4, the second face 2-4, and the third face 3-4 contains metal atoms. The average concentration of the metal atoms in a first side region 51-4 formed by the first face 1-4 and the third face 3-4 is lower than the average concentration of the metal atoms in each of the first face 1-4 and the third face 3-4. The first side region 51-4 is a region including a first side 13-4.

In the glass 100-4, the average concentration of the metal atoms in a second side region 52-4 formed by the second face 2-4 and the third face 3-4 is lower than the average concentration of the metal atoms in each of the second face 2-4 and the third face 3-4. The second side region 52-4 is a region including a second side 23-4.

The glass 100-4 has a fourth face 4-4 connecting the first face 1-4 to the second face 2-4. The fourth face 4-4 contains metal atoms. The average concentration of the metal atoms in a third side region 53-4 formed by the first face 1-4 and the fourth face 4-4 is lower than the average concentration of the metal atoms in each of the first face 1-4 and the fourth face 4-4. The average concentration of the metal atoms in a fourth side region 54-4 formed by the second face 2-4 and the fourth face 4-4 is lower than the average concentration of the metal atoms in each of the second face 2-4 and the fourth face 4-4. The third side region 53-4 is a region including a third side 14-4 (also referred to as a third chamfered portion 14-4). The fourth side region 54-4 is a region including a fourth side 24-4 (also referred to as a fourth chamfered portion 24-4).

The glass 100-4 has a fifth face 5-4 connecting the first face 1-4 to the second face 2-4. The fifth face 5-4 contains metal atoms. The average concentration of the metal atoms in a fifth side region 55-4 formed by the first face 1-4 and the fifth face 5-4 is lower than the average concentration of the metal atoms in each of the first face 1-4 and the fifth face 5-4. The average concentration of the metal atoms in a sixth side region 56-4 formed by the second face 2-4 and the fifth face 5-4 is lower than the average concentration of the metal atoms in each of the second face 2-4 and the fifth face 5-4. The fifth side region 55-4 is a region including a fifth side 15-4. The sixth side region 56-4 is a region including a sixth side 25-4.

The glass 100-4 has a sixth face 6-4 connecting the first face 1-4 to the second face 2-4. The sixth face 6-4 contains metal atoms. The average concentration of the metal atoms in a seventh side region 57-4 formed by the first face 1-4 and the sixth face 6-4 is lower than the average concentration of the metal atoms in each of the first face 1-4 and the sixth face 6-4. The average concentration of the metal atoms in an eighth side region 58-4 formed by the second face 2-4 and the sixth face 6-4 is lower than the average concentration of the metal atoms in each of the second face 2-4 and the sixth face 6-4. The seventh side region 57-4 is a region including a seventh side 16-4 (also referred to as a seventh chamfered portion 16-4). The eighth side region 58-4 is a region including an eighth side 26-4 (also referred to as an eighth chamfered portion 26-4).

In the glass 100-4, the average concentration of the metal atoms in a ninth side region 59-4 formed by the third face 3-4 and the fourth face 4-4 is lower than the average concentration of the metal atoms in each of the third face 3-4 and the fourth face 4-4. The average concentration of the metal atoms in a tenth side region 60-4 formed by the fourth face 4-4 and the fifth face 5-4 is lower than the average concentration of the metal atoms in each of the fourth face 4-4 and the fifth face 5-4. The average concentration of the metal atoms in an eleventh side region 61-4 formed by the fifth face 5-4 and the sixth face 6-4 is lower than the average concentration of the metal atoms in each of the fifth face 5-4 and the sixth face 6-4. Moreover, the average concentration of the metal atoms in a twelfth side region 62-4 formed by the sixth face 6-4 and the third face 3-4 is lower than the average concentration of the metal atoms in each of the sixth face 6-4 and the third face 3-4. The ninth side region 59-4 is a region including a ninth side 340-4. The tenth side region 60-4 is a region including a tenth side 450-4. The eleventh side region 61-4 is a region including an eleventh side 560-4. The twelfth side region 62-4 is a region including a twelfth side 630-4.

In FIG. 4, the third side region 53-4, the fourth side region 54-4, the seventh side region 57-4, and the eighth side region 58-4 each have a chamfered shape. Moreover, at least one of the first side region 51-4, the second side region 52-4, the fifth side region 55-4, and the sixth side region 56-4 may have a chamfered shape.

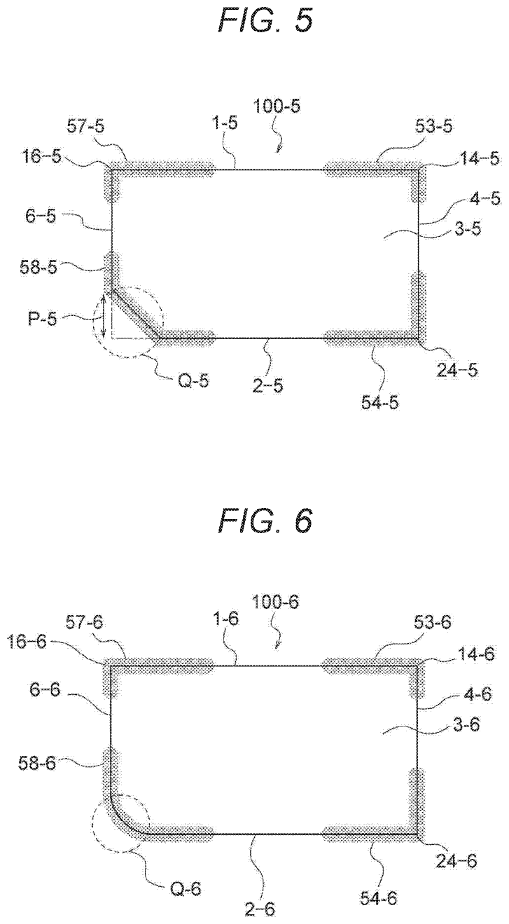

Hereinafter, the chamfered shape will be described in detail with reference to FIGS. 5 and 6.

FIG. 5 is a cross-sectional view of a glass 100-5 having a C-chamfered shape. The glass 100-5 has a first face (upper face) 1-5, a second face (lower face) 2-5, and a fourth face (end face) 4-5 and a sixth face (end face) 6-5 connecting the first face (upper face) 1-5 to the second face (lower face) 2-5. In the glass 100-5, a third side region 53-5 is formed by the first face 1-5 and the fourth face 4-5, a fourth side region 54-5 is formed by the second face 2-5 and the fourth face 4-5, a seventh side region 57-5 is formed by the first face 1-5 and the sixth face 6-5, and an eighth side region 58-5 is formed by the second face 2-5 and the sixth face 4-5.

The third side region 53-5 includes a third side 14-5, the fourth side region 54-5 includes a fourth side 24-5, and the seventh side region 57-5 includes a seventh side 16-5. The eighth side region 58-5 includes a C chamfer Q-5. A C-chamfering width P-5 of the C-chamfer Q-5 may be any width, but a C-chamfered shape having the width P-5 within a range influenced by an internal stress (tensile stress) is preferable. In a case where the chamfering width is larger than the width P-5, the C face is regarded as a face, and it is preferable not to reduce the concentration of the metal atoms on the face. For example, in a case where the thickness of the glass 100-5, that is, the length of each of the fourth face (end face) 4-5 and the sixth face (end face) 6-5 (a vertical length in FIG. 5) is about 700 μm, the width P-5 is preferably less than 200 μm.

FIG. 6 is a cross-sectional view of a glass 100-6 having an R-chamfered shape. The glass 100-6 has a first face (upper face) 1-6, a second face (lower face) 2-6, and a fourth face (end face) 4-6 and a sixth face (end face) 6-6 connecting the first face (upper face) 1-6 to the second face (lower face) 2-6. In the glass 100-6, a third side region 53-6 is formed by the first face 1-6 and the fourth face 4-6, a fourth side region 54-6 is formed by the second face 2-6 and the fourth face 4-6, a seventh side region 57-6 is formed by the first face 1-6 and the sixth face 6-6, and an eighth side region 58-6 is formed by the second face 2-6 and the sixth face 4-6.

The third side region 53-6 includes a third side 14-6, the fourth side region 54-6 includes a fourth side 24-6, and the seventh side region 57-6 includes a seventh side 16-6. The eighth side region 58-6 includes an R chamfer Q-6. The R-chamfering width (radius) of the R-chamfer Q-6 may be any width, but an R-chamfered shape having a width (radius) within a range influenced by an internal stress (tensile stress) is preferable. In a case where the chamfering width (radius) is larger than the above width, the R face is regarded as a face, and it is preferable not to reduce the concentration of the metal atoms on the face. For example, in a case where the thickness of the glass 100-6, that is, the length of each of the fourth face (end face) 4-6 and the sixth face (end face) 6-6 (a vertical length in FIG. 6) is about 700 μm, the radius of the R-chamfer is preferably less than 200 μm.

### 5. Fourth Embodiment (Example 4 of Glass)

A glass according to a fourth embodiment of the present technology has the same configuration as the glass according to the first embodiment of the present technology described above, and moreover has at least a fourth face connecting the first face to the second face. In the glass according to the fourth embodiment of the present technology, the fourth face contains the metal atoms, and the average concentration of the metal atoms in a vertex portion formed by a first side region and a third side region formed by the first face and the fourth face is lower than the average concentration of the metal atoms in each of the first side region and the third side region. Furthermore, in the glass according to the fourth embodiment of the present technology, the average concentration of the metal atoms in a vertex portion formed by a second side region and a fourth side region formed by the second face and the fourth face may be lower than the average concentration of the metal atoms in each of the second side region and the fourth side region.

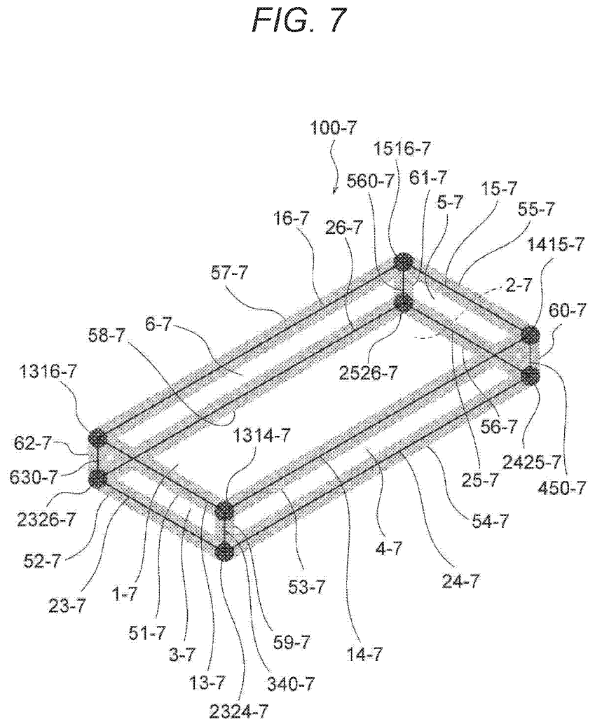

FIG. 7 illustrates a glass 100-7 which is an example of the glass according to the fourth embodiment of the present technology. FIG. 7 is a perspective view of the glass 100-7.

The glass 100-7 has at least a first face 1-7 and a second face 2-7 facing each other, and a third face 3-7 connecting the first face 1-7 to the second face 2-7. Each of the first face 1-7, the second face 2-7, and the third face 3-7 contains metal atoms. The average concentration of the metal atoms in a first side region 51-7 formed by the first face 1-7 and the third face 3-7 is lower than the average concentration of the metal atoms in each of the first face 1-7 and the third face 3-7. The first side region 51-7 is a region including a first side 13-7.

In the glass 100-7, the average concentration of the metal atoms in a second side region 52-7 formed by the second face 2-7 and the third face 3-7 is lower than the average concentration of the metal atoms in each of the second face 2-7 and the third face 3-7. The second side region 52-7 is a region including a second side 23-7.

The glass 100-7 has a fourth face 4-7 connecting the first face 1-7 to the second face 2-7. The fourth face 4-7 contains metal atoms. The average concentration of the metal atoms in a third side region 53-7 formed by the first face 1-7 and the fourth face 4-7 is lower than the average concentration of the metal atoms in each of the first face 1-7 and the fourth face 4-7. The average concentration of the metal atoms in a fourth side region 54-7 formed by the second face 2-7 and the fourth face 4-7 is lower than the average concentration of the metal atoms in each of the second face 2-7 and the fourth face 4-7. The third side region 53-7 is a region including a third side 14-7. The fourth side region 54-7 is a region including a fourth side 24-7.

The glass 100-7 has a fifth face 5-7 connecting the first face 1-7 to the second face 2-7. The fifth face 5-7 contains metal atoms. The average concentration of the metal atoms in a fifth side region 55-7 formed by the first face 1-7 and the fifth face 5-7 is lower than the average concentration of the metal atoms in each of the first face 1-7 and the fifth face 5-7. The average concentration of the metal atoms in a sixth side region 56-7 formed by the second face 2-7 and the fifth face 5-7 is lower than the average concentration of the metal atoms in each of the second face 2-7 and the fifth face 5-7. The fifth side region 55-7 is a region including a fifth side 15-7. The sixth side region 56-7 is a region including a sixth side 25-7.

The glass 100-7 has a sixth face 6-7 connecting the first face 1-7 to the second face 2-7. The sixth face 6-7 contains metal atoms. The average concentration of the metal atoms in a seventh side region 57-7 formed by the first face 1-7 and the sixth face 6-7 is lower than the average concentration of the metal atoms in each of the first face 1-7 and the sixth face 6-7. The average concentration of the metal atoms in an eighth side region 58-7 formed by the second face 2-7 and the sixth face 6-7 is lower than the average concentration of the metal atoms in each of the second face 2-7 and the sixth face 6-7. The seventh side region 57-7 is a region including a seventh side 16-7. The eighth side region 58-7 is a region including an eighth side 26-7.

In the glass 100-7, the average concentration of the metal atoms in a ninth side region 59-7 formed by the third face 3-7 and the fourth face 4-7 is lower than the average concentration of the metal atoms in each of the third face 3-7 and the fourth face 4-7. The average concentration of the metal atoms in a tenth side region 60-7 formed by the fourth face 4-7 and the fifth face 5-7 is lower than the average concentration of the metal atoms in each of the fourth face 4-7 and the fifth face 5-7. The average concentration of the metal atoms in an eleventh side region 61-7 formed by the fifth face 5-7 and the sixth face 6-7 is lower than the average concentration of the metal atoms in each of the fifth face 5-7 and the sixth face 6-7. Moreover, the average concentration of the metal atoms in a twelfth side region 62-7 formed by the sixth face 6-7 and the third face 3-7 is lower than the average concentration of the metal atoms in each of the sixth face 6-7 and the third face 3-7. The ninth side region 59-7 is a region including a ninth side 340-7. The tenth side region 60-7 is a region including a tenth side 450-7. The eleventh side region 61-7 is a region including an eleventh side 560-7. The twelfth side region 62-7 is a region including a twelfth side 630-7.

In the glass 100-7, the average concentration of the metal atoms in a vertex portion 1314-7 formed by the first side region 51-7 and the third side region 53-7 is lower than the average concentration of the metal atoms in each of the first side region 51-7 and the third side region 53-7. The vertex portion 1314-7 and the vicinity of the vertex portion 1314-7 are surrounded by the first face 1-7, the third face 3-7, and the fourth face 4-7, and tend to have a higher internal stress. Therefore, it may be effective to reduce the average concentration in the vertex portion 1324-7. Note that the vertex portion 1314-7 may be formed by the first side region 51-7, the third side region 53-7, and the ninth side region 59-7.

In the glass 100-7, the average concentration of the metal atoms in a vertex portion 2324-7 formed by the first side region 52-7 and the fourth side region 54-7 is lower than the average concentration of the metal atoms in each of the second side region 52-7 and the fourth side region 54-7. The vertex portion 2324-7 and the vicinity of the vertex portion 2324-7 are surrounded by the second face 2-7, the third face 3-7, and the fourth face 4-7, and tend to have a higher internal stress. Therefore, it may be effective to reduce the average concentration in the vertex portion 2324-7. Note that the vertex portion 2324-7 may be formed by the second side region 52-7, the fourth side region 54-7, and the ninth side region 59-7.

In the glass 100-7, the average concentration of the metal atoms in a vertex portion 1415-7 formed by the third side region 53-7 and the fifth side region 55-7 is lower than the average concentration of the metal atoms in each of the third side region 53-7 and the fifth side region 55-7. The vertex portion 1415-7 and the vicinity of the vertex portion 1415-7 are surrounded by the first face 1-7, the fourth face 4-7, and the fifth face 5-7, and tend to have a higher internal stress. Therefore, it may be effective to reduce the average concentration in the vertex portion 1415-7. Note that the vertex portion 1415-7 may be formed by the third side region 53-7, the fifth side region 55-7, and the tenth side region 60-7.

In the glass 100-7, the average concentration of the metal atoms in a vertex portion 2425-7 formed by the fourth side region 54-7 and the sixth side region 56-7 is lower than the average concentration of the metal atoms in each of the fourth side region 54-7 and the sixth side region 56-7. The vertex portion 2425-7 and the vicinity of the vertex portion 2425-7 are surrounded by the second face 2-7, the fourth face 4-7, and the fifth face 5-7, and tend to have a higher internal stress. Therefore, it may be effective to reduce the average concentration in the vertex portion 2425-7. Note that the vertex portion 2425-7 may be formed by the fourth side region 54-7, the sixth side region 56-7, and the tenth side region 60-7.

In the glass 100-7, the average concentration of the metal atoms in a vertex portion 1516-7 formed by the fifth side region 55-7 and the seventh side region 57-7 is lower than the average concentration of the metal atoms in each of the fifth side region 55-7 and the seventh side region 57-7. The vertex portion 1516-7 and the vicinity of the vertex portion 1516-7 are surrounded by the first face 1-7, the fifth face 5-7, and the sixth face 6-7, and tend to have a higher internal stress. Therefore, it may be effective to reduce the average concentration in the vertex portion 1516-7. Note that the vertex portion 1516-7 may be formed by the fifth side region 55-7, the seventh side region 57-7, and the eleventh side region 61-7.

In the glass 100-7, the average concentration of the metal atoms in a vertex portion 2526-7 formed by the sixth side region 56-7 and the eighth side region 58-7 is lower than the average concentration of the metal atoms in each of the sixth side region 56-7 and the eighth side region 58-7. The vertex portion 2526-7 and the vicinity of the vertex portion 2526-7 are surrounded by the second face 2-7, the fifth face 5-7, and the sixth face 6-7, and tend to have a higher internal stress. Therefore, it may be effective to reduce the average concentration in the vertex portion 2526-7. Note that the vertex portion 2526-7 may be formed by the sixth side region 56-7, the eighth side region 58-7, and the eleventh side region 61-7.

In the glass 100-7, the average concentration of the metal atoms in a vertex portion 1316-7 formed by the seventh side region 57-7 and the first side region 51-7 is lower than the average concentration of the metal atoms in each of the seventh side region 57-7 and the first side region 51-7. The vertex portion 1316-7 and the vicinity of the vertex portion 1316-7 are surrounded by the first face 1-7, the sixth face 6-7, and the third face 3-7, and tend to have a higher internal stress. Therefore, it may be effective to reduce the average concentration in the vertex portion 1316-7. Note that the vertex portion 1316-7 may be formed by the seventh side region 57-7, the first side region 51-7, and the twelfth side region 62-7.

In the glass 100-7, the average concentration of the metal atoms in a vertex portion 2326-7 formed by the eighth side region 58-7 and the second side region 52-7 is lower than the average concentration of the metal atoms in each of the eighth side region 58-7 and the second side region 52-7. The vertex portion 2326-7 and the vicinity of the vertex portion 2326-7 are surrounded by the second face 2-7, the sixth face 6-7, and the third face 3-7, and tend to have a higher internal stress. Therefore, it may be effective to reduce the average concentration in the vertex portion 2326-7. Note that the vertex portion 2326-7 may be formed by the eighth side region 58-7, the second side region 52-7, and the twelfth side region 62-7.

### 6. Fifth Embodiment (Example of Casing)

A casing (an example of a casing) according to a fifth embodiment of the present technology is a casing including any one of the glasses according to the first to fourth embodiments of the present technology. Since the casing according to the fifth embodiment of the present technology includes the above-described glass having excellent strength, a user can robustly handle the casing according to the fifth embodiment of the present technology.

### 7. Sixth Embodiment (Example of Electronic Device)

An electronic device (an example of an electronic device) according to a sixth embodiment of the present technology is an electronic device including any one of the glasses according to the first to fourth embodiments of the present technology. Since the electronic device according to the sixth embodiment of the present technology includes the above-described glass having excellent strength, a user can robustly handle the electronic device according to the fifth embodiment of the present technology.

The electronic device according to the sixth embodiment of the present technology includes, for example, any one of the glasses according to the first to fourth embodiments of the present technology as a cover glass, and moreover, includes a casing having two main faces (front surface and back surface) facing each other and four side faces (outer peripheral faces) connected to the two main faces, and a display, in which the cover glass covers the display.

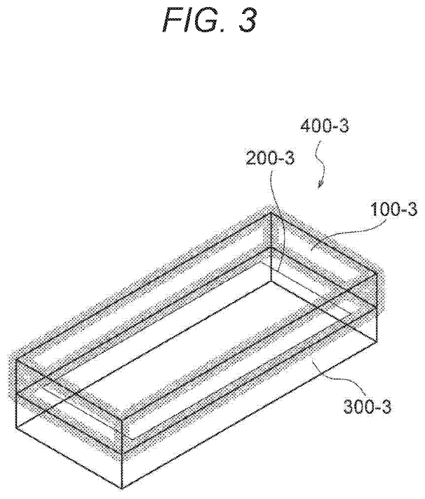

FIG. 3 illustrates an electronic device 400-3 which is an example of the electronic device according to the sixth embodiment of the present technology. FIG. 3 is a perspective view of the electronic device 400-3.

The electronic device 400-3 includes a glass 100-3, a display 200-3, and a casing 300-3. As illustrated in FIG. 3, in the electronic device 400-3, the display 200-3 is disposed at an upper part of the casing 300-3 (upward in FIG. 3), and the glass 100-3 is disposed as a cover glass so as to cover the display 200-3.

### 8. Examples of Use of Solid-State Imaging Element to Which the Present Technology is Applied

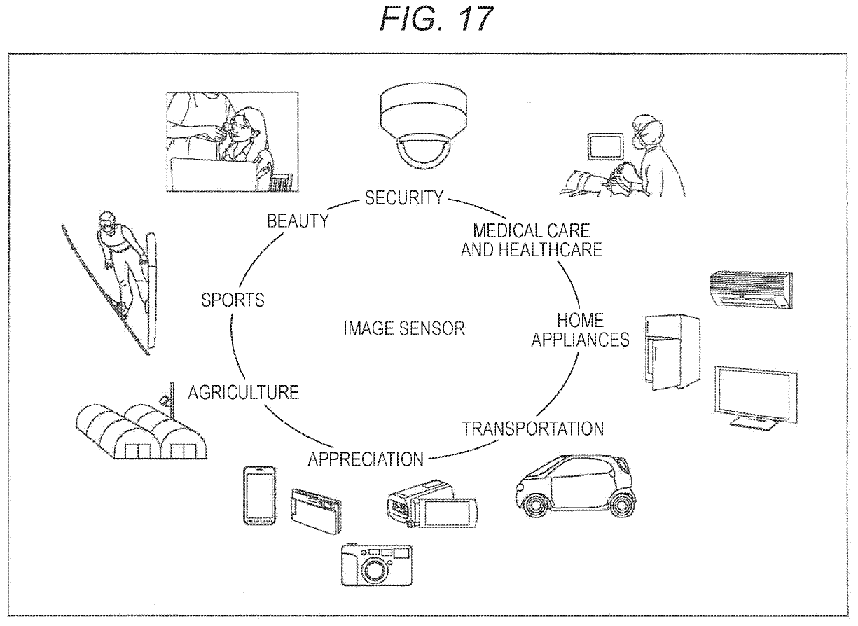

FIG. 17 is a diagram illustrating an example of use of the electronic device according to the sixth embodiment of the present technology as a device including an image sensor.

The above-described electronic device according to the sixth embodiment can be used, for example, in various cases of sensing light such as visible light, infrared light, ultraviolet light, or an X-ray as described below. That is, as illustrated in FIG. 17, the electronic device according to the sixth embodiment of the present technology can be used as a device used in, for example, a field of appreciation for capturing an image for appreciation, a field of transportation, a field of home appliances, a field of medical care and healthcare, a field of security, a field of beauty, a field of sports, a field of agriculture, and the like.

Specifically, in the field of appreciation, the electronic device according to the sixth embodiment of the present technology can be used, for example, as a device for capturing an image for appreciation, such as a digital camera, a smartphone, or a mobile phone with a camera function.

In the field of transportation, the electronic device according to the sixth embodiment of the present technology can be used, for example, as a device for transportation, such as a vehicle-mounted sensor for imaging the front, the back, the surrounding, the inside, or the like of an automobile for safe driving such as automatic stop, for recognition of a driver's condition, and the like, a monitoring camera for monitoring a running vehicle and a road, or a measuring sensor for measuring a distance between vehicles or the like

In the field of home appliances, the electronic device according to the sixth embodiment of the present technology can be used, for example, as a device for home appliances such as a television receiver, a refrigerator, and an air conditioner for imaging a user's gesture and performing device operation according to the gesture.

In the field of medical care and healthcare, the electronic device according to the sixth embodiment of the present technology can be used, for example, as a device for medical care and healthcare, such as an endoscope or a device for performing blood vessel imaging by receiving infrared light.

In the field of security, the electronic device according to the sixth embodiment of the present technology can be used, for example, as a device for security, such as a monitoring camera for security use or a camera for person authentication.

In the field of beauty, the electronic device according to the sixth embodiment of the present technology can be used, for example, as a device for beauty, such as a skin measuring device for imaging the skin or a microscope for imaging the scalp.

In the field of sports, the electronic device according to the sixth embodiment of the present technology can be used, for example, as a device for sports, such as an action camera or a wearaple camera for sports use or the like.

In the field of agriculture, the electronic device according to the sixth embodiment of the present technology can be used, for example, as a device for agriculture, such as a camera for monitoring the state of a field or a crop.

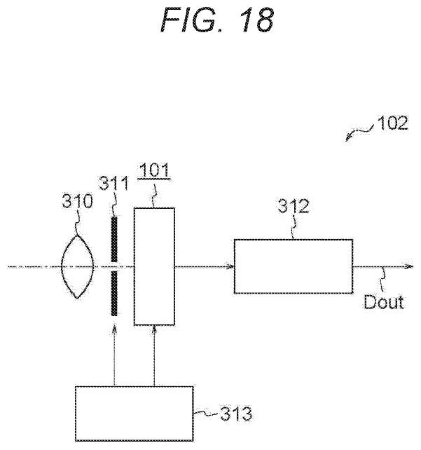

Next, an example of the electronic device according to the sixth embodiment of the present technology will be specifically described. For example, the electronic device according to the sixth embodiment of the present technology can be used as any type of electronic device having an imaging function, such as a camera system including, for example, a digital still camera and a video camera, a mobile phone having an imaging function, and the like. FIG. 18 illustrates a schematic configuration of an electronic device 102 (camera) as an example. The electronic device 102 is, for example, a video camera capable of capturing a still image or a moving image, and includes a solid-state imaging element 101, an optical system (optical lens) 310, a shutter device 311, a drive unit 313 that drives the solid-state imaging element 101 and the shutter device 311, and a signal processing unit 312.

The optical system 310 guides image light (incident light) from a subject to a pixel unit 101a of the solid-state imaging element 101. This optical system 310 may include a plurality of optical lenses. The shutter device 311 controls a light irradiation period and a light blocking period to the solid-state imaging element 101. The drive unit 313 controls a transfer operation of the solid-state imaging element 101 and a shutter operation of the shutter device 311. The signal processing unit 312 performs various types of signal processing on a signal output from the solid-state imaging element 101. A video signal Dout after the signal processing is stored in a storage medium such as a memory or is output to a monitor and the like.

Note that the embodiments of the present technology are not limited to the above-described embodiments, and various modifications can be made thereto without departing from the gist of the present technology.

Furthermore, the effects described here are merely examples, and the effects of the present technology are not limited thereto, and may include other effects.

Furthermore, the present technology can have the following configurations.
[1]

A glass having at least a first face and a second face facing each other, and a third face connecting the first face to the second face, in which

each of the first face, the second face, and the third face contains metal atoms, and

the average concentration of the metal atoms in a first side region formed by the first face and the third face is lower than

the average concentration of the metal atoms in each of the first face and the third face.
[2]

The glass according to [1], in which the first side region has a chamfered shape.
[3]

The glass according to [2], in which the chamfered shape is a C-chamfered shape.
[4]

The glass according to [2], in which the chamfered shape is an R-chamfered shape.
[5]

The glass according to any one of [1] to [4], in which the average concentration of the metal atoms in a second side region formed by the second face and the third face is lower than the average concentration of the metal atoms in each of the second face and the third face.
[6]

The glass according to [5], in which the second side region has a chamfered shape.
[7]

The glass according to [6], in which the chamfered shape is a C-chamfered shape.
[8]

The glass according to [6], in which the chamfered shape is an R-chamfered shape.
[9]

The glass according to any one of [1] to [8], further having at least a fourth face connecting the first face to the second face, in which

the fourth face contains the metal atoms, and

the average concentration of the metal atoms in a vertex portion formed by the first side region and a third side region formed by the first face and the fourth face is lower than the average concentration of the metal atoms in each of the first side region and the third side region.
[10]

The glass according to any one of [1] to [9], further having at least a fourth face connecting the first face to the second face, in which

the fourth face contains the metal atoms, and

the average concentration of the metal atoms in a vertex portion formed by a second side region formed by the second face and the third face and a fourth side region formed by the second face and the fourth face is lower than the average concentration of the metal atoms in each of the second side region and the fourth side region.
[11]

The glass according to any one of [1] to [10], in which at least one of the first face and the second face is a flat face.
[12]

The glass according to any one of [1] to [11], in which at least one of the first face and the second face is a curved face.
[13]

A casing including the glass according to any one of [1] to [12].
[14]

An electronic device including the glass according to any one of [1] to [12].

### REFERENCE SIGNS LIST

100(100-1) Glass
1-1 First face
2-1 Second face
3-1 Third face
51-1 First side region

1. A glass having at least a first face and a second face facing each other, and a third face connecting the first face to the second face, wherein
each of the first face, the second face, and the third face contains metal atoms, and
an average concentration of the metal atoms in a first side region formed by the first face and the third face is lower than
an average concentration of the metal atoms in each of the first face and the third face.

2. The glass according to claim 1, wherein the first side region has a chamfered shape.

3. The glass according to claim 2, wherein the chamfered shape is a C-chamfered shape.

4. The glass according to claim 2, wherein the chamfered shape is an R-chamfered shape.

5. The glass according to claim 1, wherein an average concentration of the metal atoms in a second side region formed by the second face and the third face is lower than an average concentration of the metal atoms in each of the second face and the third face.

6. The glass according to claim 5, wherein the second side region has a chamfered shape.

7. The glass according to claim 6, wherein the chamfered shape is a C-chamfered shape.

8. The glass according to claim 6, wherein the chamfered shape is an R-chamfered shape.

9. The glass according to claim 1, further having at least a fourth face connecting the first face to the second face, wherein
the fourth face contains the metal atoms, and
an average concentration of the metal atoms in a vertex portion formed by the first side region and a third side region formed by the first face and the fourth face is lower than an average concentration of the metal atoms in each of the first side region and the third side region.

10. The glass according to claim 1, further having at least a fourth face connecting the first face to the second face, wherein
the fourth face contains the metal atoms, and
an average concentration of the metal atoms in a vertex portion formed by a second side region formed by the second face and the third face and a fourth side region formed by the second face and the fourth face is lower than an average concentration of the metal atoms in each of the second side region and the fourth side region.

11. The glass according to claim 1, wherein at least one of the first face and the second face is a flat face.

12. The glass according to claim 1, wherein at least one of the first face and the second face is a curved face.

13. A casing comprising the glass according to claim 1.

14. An electronic device comprising the glass according to claim 1.
